(19) United States
(12) Patent Application Publication
(10) Pub. No.: US 2024/0079236 A1
(43) Pub. Date: Mar. 7, 2024

(54) SiC MOSFET Including Trench with Rounded Corners

(71) Applicant: Applied Materials, Inc., Santa Clara, CA (US)

(72) Inventors: Qintao Zhang, Mt Kisco, NY (US); Sipeng Gu, Clifton Park, NY (US)

(73) Assignee: Applied Materials, Inc., Santa Clara, CA (US)

(21) Appl. No.: 17/902,551

(22) Filed: Sep. 2, 2022

(51) Int. Cl. H01L 21/04; H01L 29/06; H01L 29/16; H01L 29/66

(52) U.S. Cl. CPC H01L 21/0475; H01L 21/0465; H01L 29/063; H01L 29/1608; H01L 29/66068

(57) ABSTRACT

Disclosed herein are approaches for forming a SiC MOSFET including at least one trench with rounded corners. In one approach, a method may include providing a masking layer over a silicon carbide (SiC) layer, wherein an opening is formed in the masking layer, and providing a sidewall spacer along a sidewall of the opening of the masking layer. The method may further include forming an implant region within the SiC layer by directing ions through the opening defined by the sidewall spacer, performing a first etch to the SiC layer, wherein the first etch forms a central recess and a set of shoulder regions adjacent the central recess, and performing a second etch to remove the set of shoulder regions.

### FIELD OF THE DISCLOSURE

The present disclosure relates to semiconductor structures and, more particularly, to an implantation assisted trench etch for SiC MOSFET scaling.

### BACKGROUND OF THE DISCLOSURE

Metal oxide semiconductor field effect transistors (MOSFET) are a type of field effect transistor (FET) that can be used for switching electronic signals. The MOSFET has a source, a drain, and a metal oxide gate electrode. A channel region communicatively couples the source to the drain. The metal gate is electrically insulated from the channel region by a thin layer of insulating material, for example, silicon dioxide or high dielectric constant (i.e., high-k) dielectrics, which makes the input resistance of the MOSFET relatively high. The gate voltage controls whether or not the channel region conducts, thereby determining whether or not the path from the source through the channel region to drain is an open circuit (“off”) or a resistive path (“on”).

Currently, U-shape trench MOSFET are used to enable further pitch scaling with high breakdown voltage. Methods used in Si-trench MOSFETs, such as sacrificial oxidation and hydrogen annealing, are impractical for SiC MOSFETs processes, however, because current etch methods can only generate rounded corners with a flat region in the bottom of the Si trench. More specifically, SiC hydrogen annealing requires a high temperature, such as 1700° C., which is inappropriate when using SiO₂ as a mask during annealing, as the top corner(s) of each trench become rounded. This bigger radius on the top corner makes contact/implantation less scalable.

It is with respect to these and other drawbacks of the current art that the present disclosure is provided.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include providing a masking layer over a silicon carbide (SiC) layer, wherein an opening is formed in the masking layer, and providing a sidewall spacer along a sidewall of the opening of the masking layer. The method may further include forming an implant region within the SiC layer by directing ions through the opening defined by the sidewall spacer, performing a first etch to the SiC layer, wherein the first etch forms a central recess and a set of shoulder regions adjacent the central recess, and performing a second etch to remove the set of shoulder regions.

In another aspect, a method of forming a silicon carbide (SiC) metal-oxide-semiconductor field-effect transistor (MOSFET) may include providing a masking layer over a SiC layer, wherein an opening is formed in the masking layer, and wherein the opening defines an etch region in the SiC layer. The method may further include providing a sidewall spacer along a sidewall of the opening of the masking layer, and forming an implant region in a central area of the etch region by directing ions into the SiC layer, through the opening defined by the sidewall spacer. The method may further include performing a first etch to the SiC layer, wherein the first etch forms a central recess and a set of shoulder regions adjacent the central recess, and performing a second etch to remove the set of shoulder regions.

In yet another aspect, a method of forming a silicon carbide (SiC) metal-oxide-semiconductor field-effect transistor (MOSFET) may include providing a masking layer over a SiC layer, wherein an opening is formed in the masking layer, and wherein the opening defines an etch region in the SiC layer, and providing a sidewall spacer along a sidewall of the opening of the masking layer. The method may further include forming an implant region in a central area of the etch region by directing ions into the SiC layer, through the opening defined by the sidewall spacer, and performing a first etch to the SiC layer. The first etch may form a trench having a central recess and a set of shoulder regions adjacent the central recess. The method may further include performing a second etch to the trench to remove the set of shoulder regions.

### BRIEF DESCRIPTION OF THE DRAWINGS

The accompanying drawings illustrate exemplary approaches of the disclosure, including the practical application of the principles thereof, as follows:

FIG. 1 is a cross-sectional side view of layers of a device following an ion implant, according to embodiments of the present disclosure;

FIG. 2 is a side cross-sectional view illustrating the device following a first etch process, according to embodiments of the present disclosure;

FIG. 3 is a side cross-sectional view illustrating the device following a second etch process, according to embodiments of the present disclosure;

FIG. 4 is a side cross-sectional view illustrating the device following removal of a mask layer, according to embodiments of the present disclosure; and

FIG. 5 illustrates a schematic diagram of a processing apparatus according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods and devices in accordance with the present disclosure will now be described more fully hereinafter with reference to the accompanying drawings, where various embodiments are shown. The methods and devices may be embodied in many different forms and are not to be construed as being limited to the embodiments set forth herein. Instead, these embodiments are provided so the disclosure will be thorough and complete, and will fully convey the scope of the methods to those skilled in the art.

To address the deficiencies of the prior art described above, embodiments of the present disclosure advantageously use an ion implant to increase etch rate of a selected central portion of an etch region in a SiC layer. A subsequent dual-etch process makes a flat region in the trench bottom region rounded, thus enabling U-shape SiC trench MOSFETs. In some embodiments, each of the first and second etch processes is a dry etch.

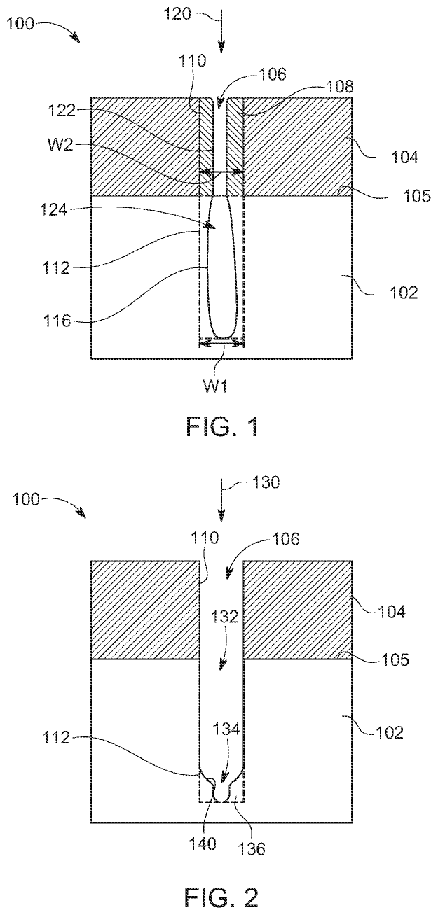

FIG. 1 is a side cross-sectional view of a portion of semiconductor device (hereinafter “device”) 100, such as a SiC MOSFET, according to one or more embodiments. As shown, the device 100 may include a stack of layers 101 including, but not limited to, a SiC layer 102 and a masking layer (SiO₂ or SiN hardmask) 104 formed atop an upper surface 105 of the SiC layer 102. It will be appreciated that other layers may be present in alternative embodiments.

As further shown, an opening 106 may be formed (e.g., etched) in the masking layer 104, and a sidewall spacer 108 may be formed along a sidewall 110 defining the opening 106. The sidewall spacer 108 may be a uniform oxide layer or other dielectric layer(s) formed using a conformal hot thermal oxide process or a dielectric deposition process, such as CVD, PVD.

Although non-limiting, the opening 106 may be formed by placing a resist over a material of the masking layer 104 and exposing it to energy (e.g., light) to form a pattern (e.g., the opening 106). An etching process with a selective chemistry, e.g., reactive ion etching (RIE), may be used to form the opening 106 in the material of the masking layer 104 through the opening of the resist.

Beneath the opening 106 is a target etch region 112 of the SiC layer 102. In some embodiments, the etch region 112 may have a width ‘W1’, which generally corresponds to a width ‘W2’ of the opening 106 together with the sidewall spacer 108. As will be described in further detail below, a trench may be later formed in the etch region 112.

An implant region 116 may then be formed within the etch region 112 of the SiC layer 102 by directing ions 120 through the opening 106 defined by the sidewall spacer 108. As shown, a width of the implant region 116 adjacent the upper surface 105 of the SiC layer 102 may be approximately the same as the opening 106 between inner surfaces 122 of the sidewall spacer 108. In other words, the implant region 116 is formed in a central area 124 of the etch region 112 and makes up less than all of the area of the etch region 112. In various embodiments, ions 120 may include one or more of the following ion species: oxygen, argon, helium, and hydrogen, phosphorus, nitrogen, aluminum. It will be appreciated that this list of species is not exhaustive, however, and that various other species may be selected to cause damage or disruption to the SiC layer.

The ion implant influences trench bottom shaping by modifying an etch rate of the implant region 116 relative to the rest of the etch region 112. That is, with a dry etch process, Si—C bonds are broken and then evaporated out. Implantation, when it helps break Si—C bonds in the SiC layer 102, in turn helps increase etch rate. Implantation depth may reach a desired etch depth delta between implanted and un-implanted areas of the etch region 112. In one non-limiting example, a 200 nm depth delta and a 15% etch rate increase due to the implant may be desired. As a result, an approximately 1400 nm implant depth may be formed. For a 2000 nm depth trench, for example, a 1400 nm deep implantation is needed to make trench center 200 nm deeper than without implantation. In one embodiment, a 1400 nm implant depth with a 1E14/cm2 dose, may reach 3E17/cm3 level doping concentration, which generates approximately a 10% etch rate increase. As shown, a depth of the implant region 116 may be approximately the same as a depth of the etch region 112.

Next, as shown in FIG. 2, a first etch 130 may be performed to the SiC layer 102, through the opening 106 of the masking layer 104. In some embodiments, the first etch 130 may be a dry etch, which forms a trench 132 having a central recess 134 and a set of shoulder regions 136 adjacent the central recess 134. The shoulder regions 136 may be defined by an interior surface 140, wherein the interior surface 140 has a first depth which is less than a second depth of the central recess 134. The shoulder regions 136 may be formed due to the etch rate delta between the implanted and un-implanted areas of the etch region 112. That is, because the ions 120 directed into the SiC layer 102 caused a greater damage to the implant region 116 (FIG. 1) relative to the remainder of the etch region 112, the etch rate is greatest in the central area 124 of the etch region 112 during the first etch 130. In some embodiments, the first etch 130 may also remove the sidewall spacer 108 from the sidewall 110 of the masking layer 104.

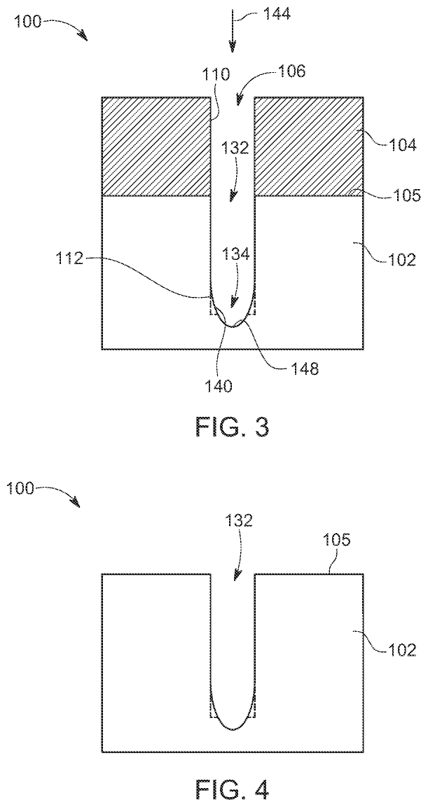

Next, as shown in FIG. 3, a second etch 144 may be performed to the SiC layer 102, through the opening 106 of the masking layer 104. As a result of the second etch 144, the shoulder regions 136 may be removed, and the central recess 134 may be further recessed into the SiC layer 102. Said another way, the first etch 130 forms the central recess 134 to a first depth relative to the upper surface 105 of the SiC layer 102, and the second etch 144 forms the central recess 134 to a second depth relative to the upper surface 105 of the SiC layer 102, wherein the second depth is greater than the first depth. Although non-limiting, a maximum depth of the central recess 134 may be greater than an original depth of the etch region 112.

In some embodiments, an inner surface 148 defining the central recess 134 may form an inverted apex or crest after the second etch 144. Meanwhile, the interior surface 140 defining the shoulder regions 136 (FIG. 2) may be generally curved or sloped towards the apex as a result of the second etch 144. By removing any sharp corners (e.g., shoulder regions 136) and any flattened regions or surfaces (e.g., the central recess 134 after the first etch 130), the trench breakdown voltage can be improved. In a typical Sic trench MOSFET design, an implantation layer, or so-called p-type shielding layer, is used to increase trench bottom breakdown voltage. This p-type shielding layer unfortunately degrades trench MOSFET on-current because it depletes the channel region in between. A U-shape trench bottom, such as the bottom of the trench 132 following the second etch 144, can reduce P-shielding doping concentration, thus improving trench MOSFET on-current.

Next, as shown, in FIG. 4, the masking layer 104 may then be removed from the upper surface 105 of the SiC layer 102, and processing of the device 100 may continue.

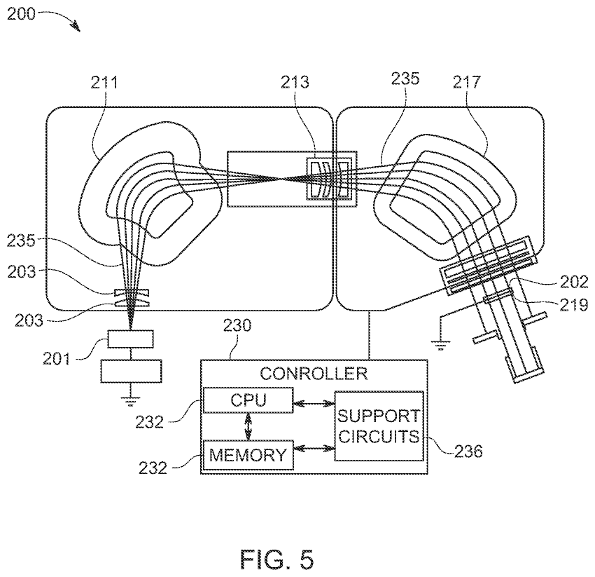

FIG. 5 illustrates a schematic diagram of a processing apparatus 200 useful to perform processes described herein. One example of a beam-line ion implantation processing apparatus is the Varian VIISTA® Trident, available from Applied Materials Inc., Santa Clara, CA. The processing apparatus 200 may include an ion source 201 for generating ions. For example, the ion source 201 may provide an ion implant, such as the oxygen ion implant 120 demonstrated in FIG. 1. The ion source 201 may also provide an ion etch, such as the first etch 130 demonstrated in FIG. 2, and the second etch 144 demonstrated in FIG. 3.

The processing apparatus 200 may also include a series of beam-line components. Examples of beam-line components may include extraction electrodes 203, a magnetic mass analyzer 211, a plurality of lenses 213, and a beam parallelizer 217. The processing apparatus 200 may also include a platen 219 for supporting a substrate 202 to be processed. The substrate 202 may be the same as the SiC layer 102 described above. The substrate 202 may be moved in one or more dimensions (e.g., translate, rotate, tilt, etc.) by a component sometimes referred to as a “roplat” (not shown). It is also contemplated that the processing apparatus 200 may be configured to perform heated implantation processes to provide for improved control of implantation characteristics, such as the ion trajectory and implantation energy utilized to dope the substrate.

In operation, ions of the desired species, for example, dopant ions, are generated and extracted from the ion source 201. Thereafter, the extracted ions 235 travel in a beam-like state along the beam-line components and may be implanted in the substrate 202. Similar to a series of optical lenses that manipulate a light beam, the beam-line components manipulate the extracted ions 235 along the ion beam. In such a manner, the extracted ions 235 are manipulated by the beam-line components while the extracted ions 235 are directed toward the substrate 202. It is contemplated that the apparatus 200 may provide for improved mass selection to implant desired ions while reducing the probability of undesirable ions (impurities) being implanted in the substrate 202.

In some embodiments, the processing apparatus 200 can be controlled by a processor-based system controller such as controller 230. For example, the controller 230 may be configured to control beam-line components and processing parameters associated with beam-line ion implantation processes. The controller 230 may include a programmable central processing unit (CPU) 232 that is operable with a memory 234 and a mass storage device, an input control unit, and a display unit (not shown), such as power supplies, clocks, cache, input/output (I/O) circuits, and the like, coupled to the various components of the processing apparatus 200 to facilitate control of the substrate processing. The controller 230 also includes hardware for monitoring substrate processing through sensors in the processing apparatus 200, including sensors monitoring the substrate position and sensors configured to receive feedback from and control a heating apparatus coupled to the processing apparatus 200. Other sensors that measure system parameters such as substrate temperature and the like, may also provide information to the controller 230.

To facilitate control of the processing apparatus 200 described above, the CPU 232 may be one of any form of general-purpose computer processor that can be used in an industrial setting, such as a programmable logic controller (PLC), for controlling various chambers and sub-processors. The memory 234 is coupled to the CPU 232 and the memory 234 is non-transitory and may be one or more of readily available memory such as random access memory (RAM), read only memory (ROM), floppy disk drive, hard disk, or any other form of digital storage, local or remote. Support circuits 236 may be coupled to the CPU 232 for supporting the processor in a conventional manner. Implantation and other processes are generally stored in the memory 234, typically as a software routine. The software routine may also be stored and/or executed by a second CPU (not shown) that is remotely located from the hardware being controlled by the CPU 232.

The memory 234 is in the form of computer-readable storage media that contains instructions, that when executed by the CPU 232, facilitates the operation of the apparatus 200. The instructions in the memory 234 are in the form of a program product such as a program that implements the method of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

It is to be understood that the various layers, structures, and regions shown in the accompanying drawings are schematic illustrations. For ease of explanation, one or more layers, structures, and regions of a type commonly used to form semiconductor devices or structures may not be explicitly shown in a given drawing. This does not imply that any layers, structures, and/or regions not explicitly shown are omitted from the actual semiconductor structures.

In various embodiments, design tools can be provided and configured to create the datasets used to pattern the semiconductor layers of the device 100, e.g., as described herein. For example, data sets can be created to generate photomasks used during lithography operations to pattern the layers for structures as described herein. Such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance running software, or implemented in hardware.

As used herein, a module might be implemented utilizing any form of hardware, software, or a combination thereof. For example, one or more processors, controllers, ASICs, PLAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading the Detailed Description, the various features and functionality described herein may be implemented in any given application and can be implemented in one or more separate or shared modules in various combinations and permutations. Although various features or elements of functionality may be individually described or claimed as separate modules, one of ordinary skill in the art will understand these features and functionality can be shared among one or more common software and hardware elements.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporating the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

As used herein, “depositing” and/or “deposited” may include any now known or later developed techniques appropriate for the material to be deposited including yet not limited to, for example: chemical vapor deposition (CVD), low-pressure CVD (LPCVD), and plasma-enhanced CVD (PECVD). Additional techniques may include semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), and sputtering deposition. Additional techniques may include ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method, comprising:
providing a masking layer over a silicon carbide (SiC) layer, wherein an opening is formed in the masking layer;
providing a sidewall spacer along a sidewall of the opening of the masking layer;
forming an implant region within the SiC layer by directing ions through the opening defined by the sidewall spacer;
performing a first etch to the SiC layer, wherein the first etch forms a central recess and a set of shoulder regions adjacent the central recess; and
performing a second etch to remove the set of shoulder regions.

2. The method of claim 1, further comprising removing the masking layer following the second etch.

3. The method of claim 2, wherein the first etch removes the sidewall spacer.

4. The method of claim 1, wherein the second etch forms an apex in the central recess.

5. The method of claim 1, wherein the implant region is located in a central area of an etch region of the SiC layer, wherein directing ions through the opening defined by the sidewall spacer causes increased damage to the implant region relative to a remainder of the etch region, and wherein the increased damage increases an etch rate of the implant region of the SiC layer during the first etch.

6. The method of claim 1, wherein providing the masking layer comprises depositing a hardmask atop the SiC layer, wherein the hardmask is silicon dioxide or silicon nitride.

7. The method of claim 1, wherein directing ions through the sidewall spacer comprises delivering at least one of the following ion species into the opening: oxygen, argon, helium, and hydrogen, phosphorus, nitrogen, and aluminum.

8. The method of claim 1, wherein the first etch forms the central recess to a first depth relative to a top surface of the SiC layer, wherein the second etch forms the central recess to a second depth relative to the top surface of the SiC layer, and wherein the second depth is greater than the first depth.

9. A method of forming a silicon carbide (SiC) metal-oxide-semiconductor field-effect transistor (MOSFET), the method comprising:
providing a masking layer over a SiC layer, wherein an opening is formed in the masking layer, and wherein the opening defines an etch region in the SiC layer;
providing a sidewall spacer along a sidewall of the opening of the masking layer;
forming an implant region in a central area of the etch region by directing ions into the SiC layer, through the opening defined by the sidewall spacer;
performing a first etch to the SiC layer, wherein the first etch forms a central recess and a set of shoulder regions adjacent the central recess; and
performing a second etch to remove the set of shoulder regions.

10. The method of claim 9, further comprising removing the masking layer following the second etch.

11. The method of claim 9, wherein the first etch removes the sidewall spacer, and wherein the second etch forms an apex in the central recess.

12. The method of claim 9, wherein directing ions through the opening defined by the sidewall spacer causes increased damage to the implant region relative to a remainder of the etch region, and wherein the increased damage increases an etch rate of the implant region of the SiC layer during the first etch.

13. The method of claim 9, wherein providing the masking layer comprises depositing a silicon dioxide hardmask atop the SiC layer, and wherein directing ions into the SiC layer comprises delivering at least one of the following ion species into the opening: oxygen, argon, helium, and hydrogen, phosphorus, nitrogen, and aluminum.

14. The method of claim 9, wherein the first etch forms the central recess to a first depth relative to a top surface of the SiC layer, wherein the second etch forms the central recess to a second depth relative to the top surface of the SiC layer, and wherein the second depth is greater than the first depth.

15. A method of forming a silicon carbide (SiC) metal-oxide-semiconductor field-effect transistor (MOSFET), the method comprising:
providing a masking layer over a SiC layer, wherein an opening is formed in the masking layer, and wherein the opening defines an etch region in the SiC layer;
providing a sidewall spacer along a sidewall of the opening of the masking layer;
forming an implant region in a central area of the etch region by directing ions into the SiC layer, through the opening defined by the sidewall spacer;
performing a first etch to the SiC layer, wherein the first etch forms a trench having a central recess and a set of shoulder regions adjacent the central recess; and
performing a second etch to the trench to remove the set of shoulder regions.

16. The method of claim 15, wherein the first etch removes the sidewall spacer, and wherein the second etch forms an apex in the central recess of the trench.

17. The method of claim 15, wherein directing ions through the opening defined by the sidewall spacer causes increased damage to the implant region relative to a remainder of the etch region, and wherein the increased damage increases an etch rate of the implant region of the SiC layer during the first etch.

18. The method of claim 15, wherein providing the masking layer comprises depositing a hardmask atop the SiC layer, wherein the hardmask is made from silicon dioxide or silicon nitride, and wherein directing ions into the SiC layer comprises delivering at least one of the following ion species through the opening: oxygen, argon, helium, hydrogen, phosphorus, nitrogen, and aluminum.

19. The method of claim 15, wherein the first etch forms the central recess to a first depth relative to a top surface of the SiC layer, wherein the second etch forms the central recess to a second depth relative to the top surface of the SiC layer, and wherein the second depth is greater than the first depth.
